(19) United States
(12) Patent Application Publication
(10) Pub. No.: US 2010/0200735 A1
(43) Pub. Date: Aug. 12, 2010

(54) OPTICAL READING SYSTEM

(75) Inventors: Anthony F. Barna, North Massapequa, NY (US); A. Arthur Kressner, Westfield, NJ (US); Lawrence P. Nardo, Brooklyn, NY (US); Charles W. Melvin, JR., Dudley, GA (US); Jason P. Walton, Byron, GA (US)

Correspondence Address: CANTOR COLBURN, LLP, 20 Church Street, 22nd Floor, Hartford, CT, 06103, US

(73) Assignees: CONSOLIDATED EDISON COMPANY OF NEW YORK, INC., New York, NY (US); SMARTSYNCH, INCORPORATED, Jackson, MS (US)

(21) Appl. No.: 12/624,653

(22) Filed: Nov. 24, 2009

Related U.S. Application Data
(60) Provisional application No. 61/151,280, filed on Feb. 10, 2009.

(51) Int. Cl. H01L 31/167; H01L 31/113

(52) U.S. Cl. 250/214.1; 250/221; 250/216

(57) ABSTRACT

An optical sensor for detecting motion or movement in an area of interest is provided. The optical sensor includes a base having optical filtering properties. A sensor assembly having a light emitting diode, a CMOS sensor and a pair of lens is mounted to said base. The CMOS sensor has a range of wavelengths of light to which it has an increased sensitivity. The optical filtering properties of the base are ranged to absorb wavelengths of light in the range of increased CMOS sensor sensitivity. In this way, the effects of ambient light on the optical sensor are reduced.

### CROSS REFERENCE TO RELATED APPLICATIONS

This application is a non-provisional application of U.S. Provisional Patent Application 61/151,280 entitled “OPTICAL READING SYSTEM” filed Feb. 10, 2009 and which is incorporated herein in its entirety.

### BACKGROUND OF THE INVENTION

The present invention relates generally to an optical sensor and more particularly to an optical sensor for detecting motion within an area of interest.

Optical sensors are used in a wide variety of applications, such as in robotics, touch screen devices and digital cameras. These optical sensors typically use either a complementary metal oxide semiconductor (“CMOS”) or a charge coupled device (“CCD”) type of sensor. The sensors use light sensitive circuitry, commonly referred to as a pixel, to convert light energy into electrical energy. Each pixel typically includes a photodiode formed in a silicon substrate. As the photodiode is exposed to light, an electrical charge is induced. The level of the charge indicates amount of light and a level of contrast can be determined by calibrating the electrical charge to a color scale. The color of the image may be determined by using either filters over the pixels or by having pixels with photodiodes that only react to certain wavelengths of light.

While optical sensors are used in a wide variety of applications, their use in some applications can be hampered due to cost. Low cost sensors are used in some applications, such as in computer mice for example, that are well defined and reasonably controlled. Absent these controls, environmental effects such as ambient light for example, typically interfere with the operation of the low cost sensor. In the case of the computer mouse, the sensor needs to be close to the surface with the mouse resting against the surface to block out light. If the mouse is lifted even a small amount, operation ceases or is greatly degraded. This limitation restricts the wide adoption of low cost optical sensors into applications where the sensor may be installed outdoors, or in an equipment room that is normally dark and periodically exposed to varying light conditions.

Thus, while existing sensing devices are suitable for their intended purposes, there remains a need for improvements. In particular, there remains a need for improvements in providing reliable, accurate and cost effective optical sensor that can be used in a wide variety environmental conditions and applications.

### SUMMARY OF THE INVENTION

An optical reading system is provided having a base plate. The base plate has an opening therethough. The base plate further provides the function of an optical filter that absorbs a range of light wavelengths. A light emitting diode (“LED”) coupled to the base plate and arranged to emit light through said opening. The LED emits light in the range of light wavelengths absorbed by the optical filter. A first lens is arranged adjacent the LED, the first lens is arranged to emit light received from the LED. A second lens is arranged adjacent the first lens. A complementary metal-oxide-semiconductor (“CMOS”) sensor adjacent the second lens and arranged to receive light received through the second lens, wherein the CMOS sensor is sensitive to light in the range of light wavelengths.

An optical reading system for detecting movement of an object is also provided. The optical reading system includes an LED and a lens member having a first lens portion adjacent the LED. The lens member is arranged to focus light received from the LED on an area of interest and a second lens portion adjacent the first lens portion and arranged to received light reflected from the area of interest, wherein the second lens portion is shaped to provide a field of view corresponding to the area of interest. A CMOS sensor is arranged adjacent the second lens and arranged to receive the reflected light and detect movement of the object within the area of interest.

Another optical reading system for detecting motion of an object within an area of interest is also provided. The optical reading system includes a power source. A base having an enclosed wall area with an opening therethrough, the base having a first portion outside of the enclosed wall area made from a translucent material having optical filtering properties for absorbing light in a wavelength range. A processor is arranged within the enclosed wall area and electrically coupled to the power source. A CMOS sensor is electrically coupled to the processor and the power source, the CMOS sensor is arranged within the enclosed wall area to receive light from the area of interest, the CMOS sensor being sensitive to the wavelength range. An LED is electrically coupled to the processor and the power source, the LED being arranged within the enclosed wall area to emit light towards the area of interest.

### BRIEF DESCRIPTION OF THE DRAWINGS

Referring now to the drawings, which are meant to be exemplary and not limiting, and wherein like elements are numbered alike:

FIG. 1 is a perspective view illustration of an optical sensor in accordance with an embodiment of the invention;

FIG. 2 is a top plan view illustration of the optical sensor of FIG. 1;

FIG. 3 is bottom plan view illustration of the optical sensor of FIG. 1;

FIG. 4 is a sectional perspective view illustration of the optical sensor of FIG. 3;

FIG. 5 is a schematic illustration of a control system for the optical sensor in accordance with an embodiment of the invention;

FIG. 6 is a schematic illustration of an LED/CMOS circuit in accordance with an embodiment of the invention;

FIG. 7 is a graphical illustration of CMOS sensor sensitivity and optical filter sensitivity versus light wavelength.

FIG. 8 is a partial top plan view illustration of an exemplary application for the optical sensor of FIG. 1; and,

FIG. 9 is a partial side plan sectional view illustration of the exemplary application of FIG. 8.

### DETAILED DESCRIPTION

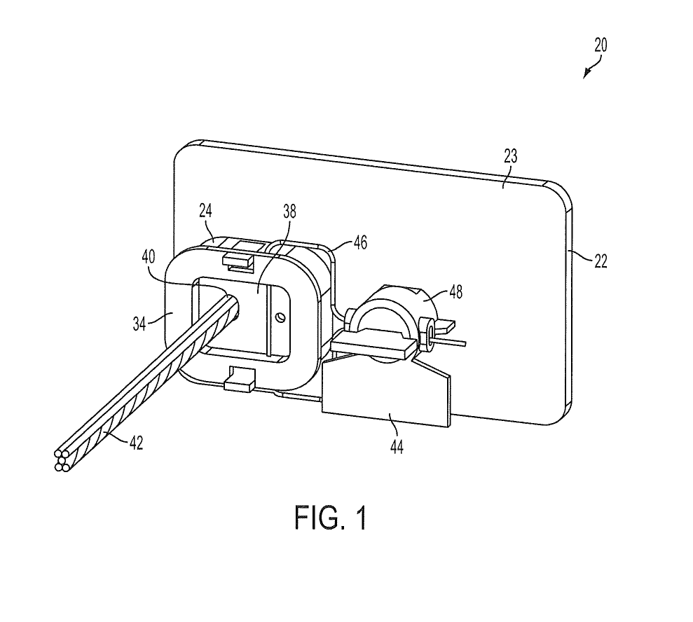

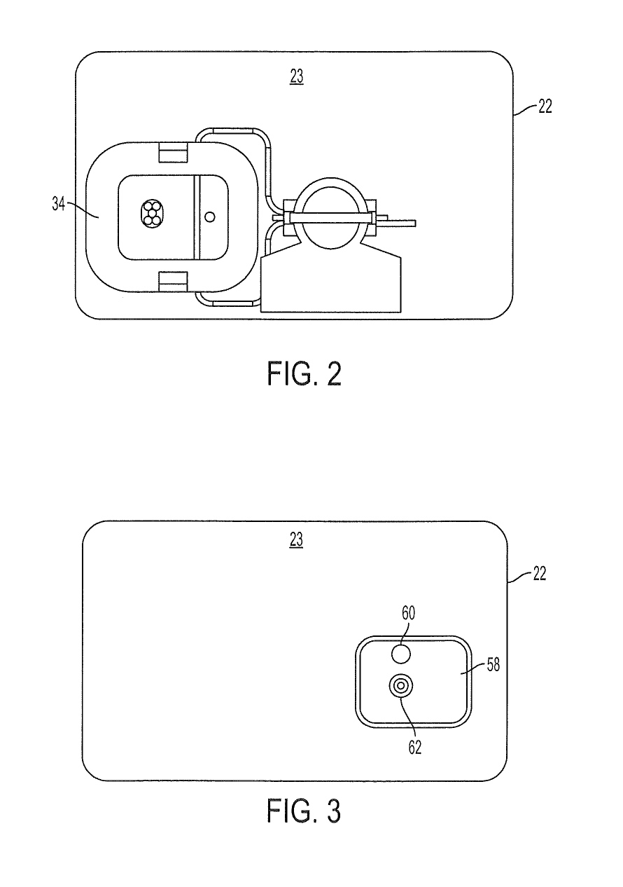

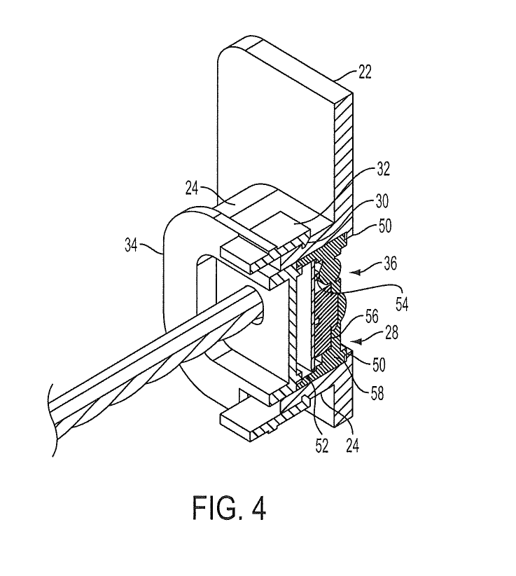

FIGS. 1-4 illustrate an exemplary embodiment of an optical sensor 20. Optical sensors may be used in a wide variety of applications where motion or other visual changes need to be monitored. The optical sensor 20 includes a base 22 having a wall 24 extending from a planar portion 23. The wall 24 encloses an area that forms an opening 28 through the base 22. In the exemplary embodiment, the planar portion 23 is made from a translucent material, such as acrylic or polycarbonate for example, which allows an operator to see the area behind the optical sensor 20. As will be discussed in more detail below, in one embodiment the base 22 or the planar portion 23 are also an optical filter that absorbs a desired range of wavelengths of light while transmitting others.

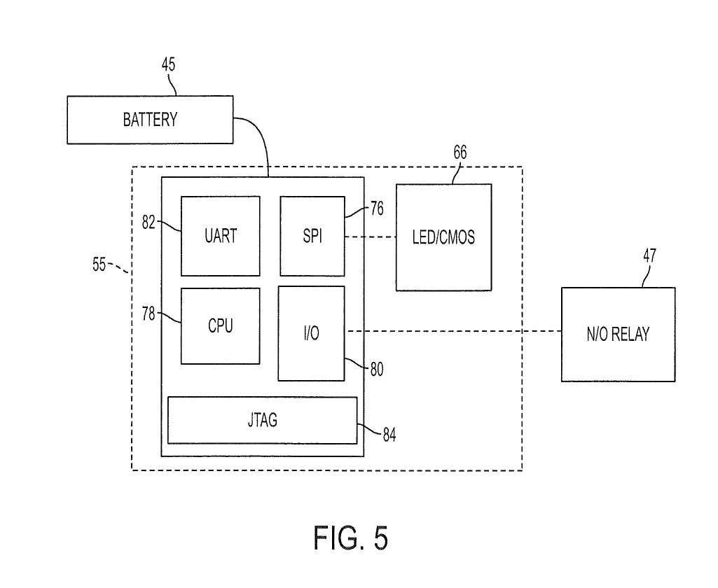

The wall 24 includes a recess 30 that is sized to receive a clip 32 on cap member 34. The clip 32 provides a snap fit connection that retains the cap member 34 on the wall 24. Cap 34 further encloses one end of the area formed by the wall 24 and retains a sensor assembly 36. The cap 34 further includes a recessed area 38. The recess 38 includes an opening 40 that allows wiring 42 from the sensor assembly 36 to exit the optical sensor 20 to be coupled to other devices such as a power source 45 (FIG. 5), a relay 47 (FIG. 5), or other control circuitry (not shown).

Optical sensor 20 may also include an optional locking assembly 44. The locking assembly 44 provides an indication to the operator if the optical sensor 20 has been tampered with. In the exemplary embodiment, the locking assembly 44 includes a wire 46 that extends from a lock mechanism 48 and through holes in the wall 24 and cap 34. The wire 46 extends across the recessed area 38 and back through an additional set of openings in the wall 24 and cap 34 on the opposite side. The wire then returned to the locking mechanism 48. In the exemplary embodiment, the locking mechanism 48 is a ratchet type mechanism that pulls the wire in only one direction allowing the wire to be securely tightened as the ratchet mechanism is engaged. Since the ratchet allows the wire 46 to be pulled in only one direction, the wire 46 needs to be cut before the cap 34 can be removed from the walls 24. Therefore, as long as the wire remains intact, the operator has some assurance that there has been no interference in the operation of the optical sensor 20.

The sensor assembly 36 is captured in the area enclosed by the wall 24 between the cap 34 and a lip 50 in the base 22. The sensor assembly 36 includes a circuit board 52 on one end having control circuitry 55 (FIG. 5) with a light emitting diode 54 and a complementary metal-oxide-semiconductor (“CMOS”) sensor 56. Opposite the circuit board 52 is a lens member 58 that forms a first or illumination lens 60 adjacent to an LED 54 and a second or focusing lens 62 adjacent a CMOS sensor 56. In the exemplary embodiment, the lens member 58 is a single piece molded out of a suitable polymer, such as polycarbonate for example, that forms both lenses 60 and 62. It should be appreciated, however, that lenses 60 and 62 may alternatively be fabricated separately and assembled into the lens member 58.

The illumination lens 60 is arranged to receive light emitted by LED 54 and focuses the light to illuminate an area of interest located adjacent to the optical sensor 20. In the exemplary embodiment, the illuminated area has a diameter of 0.06 inches to 0.08 inches and the lens has a depth of field of a ¼ inch. As will be made clearer herein, the focusing of light from the LED 54 into a small area of interest provides advantages in minimizing the impact of ambient light changes and in reducing electrical power consumption. In the exemplary embodiment, the illumination lens 60 is arranged to direct the light at an angle such that when it strikes the area of interest, it reflects back to the focus lens 62. The angle of the illumination lens 60 will depend on the application, and the distance between the illumination lens 60 and the focus lens 62.

The focus lens 62 cooperates with an aperture stop on the CMOS sensor 56 to provide the desired field of view and depth of field to receive reflected light reflected from the area of interest. By focusing on the area of interest, the CMOS sensor 56 is less susceptible to changes in the ambient light causing a false indication of movement or a change in the area of interest. As discussed above, in one embodiment, the base 22 is also an optical filter that absorbs certain wavelengths of light. Optical filtering may be absorptive, in which inorganic or organic compounds are added to the material. These compounds absorb some wavelengths of light while transmitting others. A second type of filter is a diachronic filter in which a thin film is coated on the base 22 to reflect unwanted wavelengths of light and transmit the remainder. In the exemplary embodiment, the base 22 is an absorptive filter where the compounds are additives that are molded into the base 22.

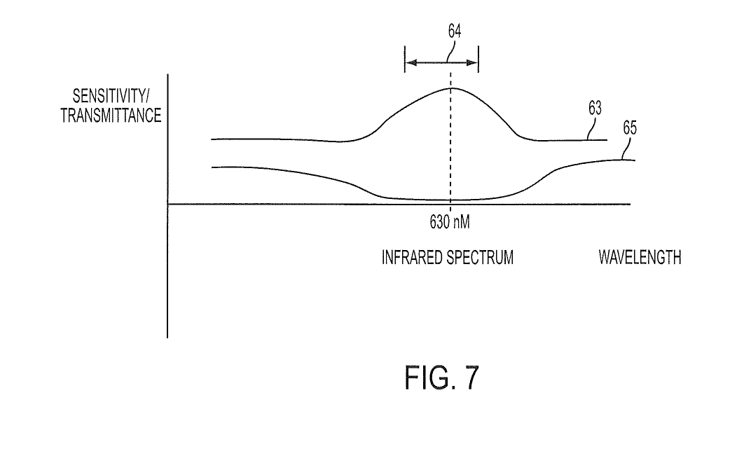

As illustrated in FIG. 7, CMOS sensor 56 may be selected to have a sensitivity profile 63 that provides for spectrums or ranges of wavelengths of light 64 in which they are more sensitive than others. In the exemplary embodiment, the CMOS sensor 56 is more sensitive in a band of wavelengths centers about 630 nanometers. Similarly, an optical filter may be tuned to have a filtering profile 65 that provides filtering to selectively absorb or reflect wavelengths of light within a desired range. By forming the base 22 as an optical filter, ambient light can be selectively filtered to minimize the potential for ambient light in having wavelengths in the range 64 from reflecting into the CMOS sensor 56. Thus the performance of the optical sensor 20 is improved while simultaneously allowing the operator to visually view the area of interest through the translucent base 22.

In the exemplary embodiment, the CMOS sensor 56 is an active-pixel sensor consisting of an integrated circuit containing an array of pixel sensors with each pixel containing a photodetector. The CMOS sensor 56 includes a two-dimensional array of pixels that is organized into rows and columns. In the exemplary embodiment, the pixel array consists of 210 elements arranged in a 14×15 array. Each of the pixels consists of a 6-bit resolution that results in 64 contrast levels. In other embodiments, the pixel array may consist of 225 elements arranged in a 15×15 array. When light strikes the pixel photodetector, a signal indicating a level of contrast is generated for that pixel. When combined with signals from the other pixels in the array, an image having 64 levels or contrast, or gray scale, may be generated.

The LED 54 is a semiconductor diode that emits light when an electrical current is applied in the forward direction of the device. The effect is a form of electroluminescence where incoherent and narrow-spectrum light is emitted from the diodes p-n junction. The color of the emitted light depends on the composition and condition of the semiconducting material used, and can be infrared, visible, or ultraviolet. In the exemplary embodiment, the color of the LED 54 is selected to produce light within the near infrared spectrum of range 64, and preferably centered on 630 nanometers, where the CMOS sensor 56 exhibits an increased sensitivity. It should be appreciated that advantages may gained in reducing power consumption by the optical sensor 20 by matching the LED 54 light color, the sensitivity range 64 of CMOS sensor 56, and the optical filtering by the base 22. By appropriate matching of these components, the brightness of the LED 54 needed to activate the photodetectors in the CMOS sensor 56 may be reduced. In the exemplary embodiment, the LED 54 and CMOS sensor 56 draw an electrical current of less than 100 micro-ampere, and more desirably less than 50 micro-ampere.

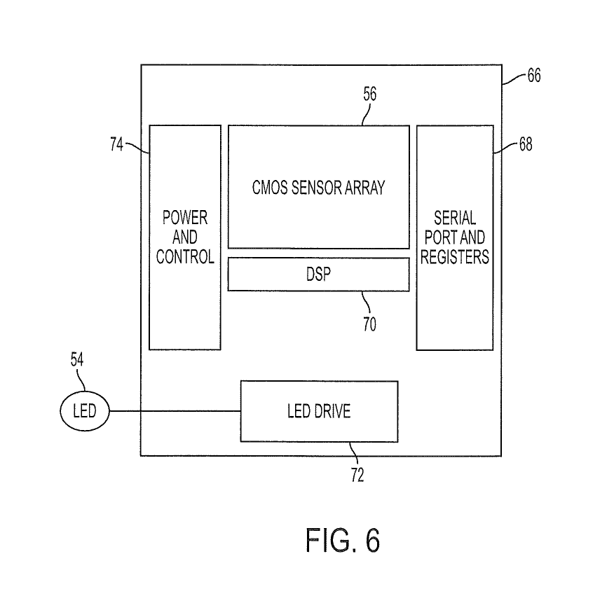

Turning now to FIG. 5 and FIG. 6, an exemplary embodiment control system for optical sensor 20 will be described. The control circuitry 55 includes a sensor integrated circuit (“IC”) 66. The sensor IC 66, such as Model ADNS-5030 sensor manufactured by Avago Technologies for example, provides a subsystem control registers and serial communications interface 68, a digital signal processor 70, the CMOS sensor array 56, an LED driver 72, LED 54, and power management circuitry 74.

The sensor IC 66 captures images using the CMOS sensor array 56. The images are acquired sequentially and then analyzed by the digital signal processor 70 to determine the direction and magnitude of any detected movement. Data related to the direction and magnitude of movement is then placed in the registers 68 where it can be accessed by other processors in control circuitry 55 via system packet interface 76.

The control circuitry also includes a microprocessor 78, such as a Model MSP430F2122 microcontroller manufactured by Texas Instruments for example. Microprocessor 78 is a suitable electronic device capable of accepting data and instructions, executing the instructions to process the data, and presenting the results. Microprocessor 78 may accept instructions through electrical transfer, such as through universal asynchronous receiver/transmitter (“UART”) 82 or via an interface such as one compliant with IEEE 1149.1 standards (“JTAG”) 84. Microprocessor 78 may also accept instructions through other means such as but not limited to a user interface, electronic data card, voice activation means, manually operable selection and control means, radiated wavelength and electronic or electrical transfer. Therefore, microprocessor 78 can be a microcomputer, a minicomputer, an optical computer, a board computer, a complex instruction set computer, an ASIC (application specific integrated circuit), a reduced instruction set computer, an analog computer, a digital computer, a molecular computer, a quantum computer, a cellular computer, a superconducting computer, a supercomputer, a solid-state computer, a single-board computer, a buffered computer, a computer network, a desktop computer, a laptop computer, or a hybrid of any of the foregoing.

In the exemplary embodiment, the microprocessor 78 has a low power standby mode that consumes less than 0.1 μA of electrical current. The microprocessor 78 has a 16-Bit RISC architecture and operates at 16 MHz. In one embodiment, the microprocessor is capable of activating from standby mode within 1 μS from an interrupt. The use of a low power microprocessor 78 and by matching the LED 56, CMOS sensor 56 and the optical filtering of base 22, the control circuitry 55 has an electrical current draw of less than 100 micro-ampere and more desirably less than 25 micro-ampere.

Microprocessor 78 includes operation control methods embodied in application code. These methods are embodied in computer instructions written to be executed by sensor IC 66 for example, typically in the form of software. The software can be encoded in any language, including, but not limited to, assembly language, VHDL (Verilog Hardware Description Language), VHSIC HDL (Very High Speed IC Hardware Description Language), Fortran (formula translation), C, C++, Visual C++, Java, ALGOL (algorithmic language), BASIC (beginners all-purpose symbolic instruction code), visual BASIC, ActiveX, HTML (HyperText Markup Language), and any combination or derivative of at least one of the foregoing. Additionally, an operator can use an existing software application such as a spreadsheet or database and correlate various cells with the variables enumerated in the algorithms. Furthermore, the software can be independent of other software or dependent upon other software, such as in the form of integrated software.

The microprocessor 78 receives data stored in the registers 68 from the sensor IC 66 via the system packet interface 76. The microprocessor 78 then determines if motion or movement is detected from the image data stored by the digital signal processor 70. The information regarding movement or motion may then be further utilized or additional actions taken. For example, where the optical sensor 20 is installed on a gauge, such as a pressure gauge for example, the area of interest may be a particular pressure. Once this pressure threshold has been crossed, the operator may need to take additional steps. These actions, which could include alarms for example, may then be carried out by the operator, or in some embodiments by the microprocessor 78. In one embodiment, the optical sensor 20 is used to measure the number of times motion is detected, such as when the gauge is an accumulator or meter for example. In this embodiment, the microprocessor causes a single pulse to issue via input/output circuitry 80 to relay 47. The relay 47 may interface the optical sensor 20 to other circuits such as an advanced metering infrastructure (“AMI”) device or Automated Meter Reading (“AMR”) device.

It should be appreciated that while the sensor IC 66 and the microprocessor 78 are described as separate components, the claimed invention should not be so limited. In one embodiment, the functionality of the sensor IC 66 and the microprocessor 78 are combined in a single integrated chip. Further, control circuitry 55 may have additional components (not shown) such as but not limited to random access memory (RAM), nonvolatile memory (NVM), read-only memory (ROM), analog-to-digital (A/D) converters and communications interfaces.

Electrical power needed by the optical sensor 20 for operation is provided by power source 45. In the exemplary embodiment, the power source 45 is a battery 45 and may be integrated onto the base 22 or remotely located to allow a smaller form factor for the sensing portion of optical sensor 20. In the exemplary embodiment, the battery 45 is a lithium thionyl chloride battery with a capacity of 19,000,000 micro-ampere hours. In the embodiments having 100 micro-ampere of current draw, this should provide an operational life of over 21 years without a requiring a change of battery 45.

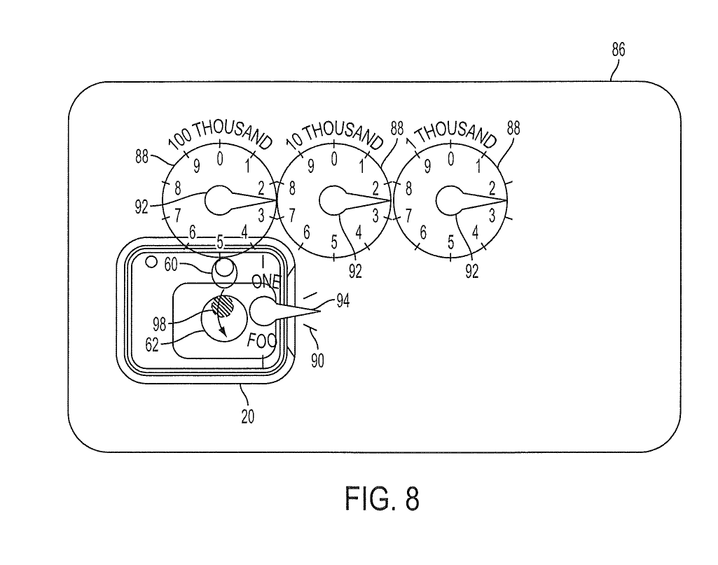

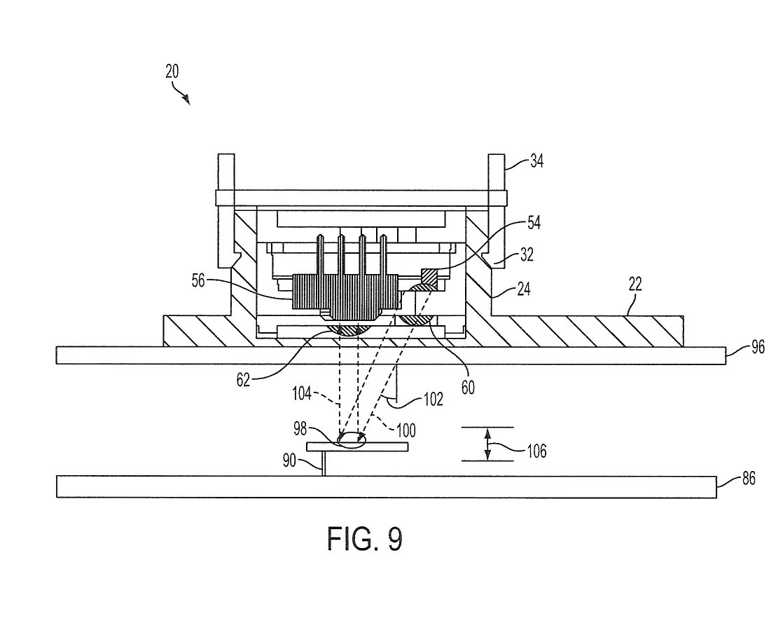

An exemplary application for optical reader 20 is illustrated in FIG. 8 and FIG. 9. In this application, that optical sensor 20 is affixed to a meter 86, such as a water, gas or electric meter for example. The meter has a plurality of dials 88 that have an indicator 92 that shows the amount of a product (e.g. water, gas or electricity) consumed. The dials 88 typically increment in response to the rotation of the indicator 94 on a measurement dial 90. A mechanical or magnetic linkage typically couples the measurement dial 90 to a measurement mechanism within the meter 86, for example. The dials 88, 90 may be located within a sealed compartment to prevent contamination and tampering.

The dials 88, 90 are viewable through a translucent window 96. The optical sensor 20 is mounted to the window 96 with the focus lens 62 and illumination lens 60 are positioned adjacent the area of interest 98. It should be appreciated that the spacing between the focus lens 62 and the illumination lens 60, along with the angle 102 that the illumination lens 60 direct the light 100 are arranged such that the area of interest 98 falls in an area that the indicator 94 travels as it rotates about the dial 90. In this way, when the indicator 94 is not in the area of interest 98, the light 100 from LED 54 reflects off of the indicator 94 and away from the focus lens 62 as indicated by arrow 104. When the indicator 94 is not present, the light 100 reflects off of the dial surface 106 and the focus lens 62 receives the reflected light. Thus the CMOS sensor 56 records the image of the indicator 94 passing through the area of interest 98.

In the exemplary embodiment, the CMOS sensor 56 records an image of the area of interest 98 on a periodic basis. By not continuously imaging the area, data storage requirements may be minimized and the power consumption reduced. As a result, depending on the speed of the dial, multiple images of the indicator 94 may be acquired as it passes through the area of interest 98. The timing of the image acquisition is controlled by instructions issued by the microprocessor 78 to the sensor IC 66. By timing the acquisition of the indicator 94 into the area of interest 98, the microprocessor 78 can receive an image of the indicator 94 entering and a separate image of the indicator 94 leaving the area of interest. The use of multiple images may then be used by the microprocessor 78 to validate that the indicator 94 has passed without the risk of double counting.

It should be appreciated that the location of the area of interest may vary over a distance as indicated by arrow 106. This variation may be due to a variety of factors, including tolerance stackup between components on meter 86, differences between models of meters and the like. The lens 60, 62 are arranged to have a field of view that accounts for this variation without having the area of interest becoming too small (when the area of interest is closer) or becoming too large (when the area of interest is farther away). In the exemplary embodiment, the area of interest has a diameter of 0.06 inches to 0.08 inches and the field of view may vary over 0.25 inches.

The optical sensor 20 provided herein includes a number of benefits and advantages. It allows the use of a low cost CMOS sensor under a variety of environmental and ambient light conditions. The base 22 performs the function of an optical filter to reduce the effect of ambient light on the operation of the optical sensor 20. The optical sensor further has a low power consumption allowing the sensor to operate without interruption for extended periods of time.

An embodiment of the invention may be embodied in the form of computer-implemented processes and apparatuses for practicing those processes. Embodiments of the present invention may also be embodied in the form of a computer program product having computer program code containing instructions embodied in tangible media, such as floppy diskettes, CD-ROMs, hard drives, USB (universal serial bus) drives, or any other computer readable storage medium, such as random access memory (RAM), read only memory (ROM), or erasable programmable read only memory (EPROM), for example, wherein, when the computer program code is loaded into and executed by a computer, the computer becomes an apparatus for practicing the invention. The embodiments of the invention may also be embodied in the form of computer program code, for example, whether stored in a storage medium, loaded into and/or executed by a computer, or transmitted over some transmission medium, such as over electrical wiring or cabling, through fiber optics, or via electromagnetic radiation, wherein when the computer program code is loaded into and executed by a computer, the computer becomes an apparatus for practicing the invention. When implemented on a general-purpose microprocessor, the computer program code segments configure the microprocessor to create specific logic circuits. One technical effect of the executable instructions is to monitor for movement or motion within an area of interest using a recorded image and measure the number of times such motion is recorded.

While the invention has been described with reference to exemplary embodiments, it will be understood that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best or only mode contemplated for carrying out this invention, but that the invention will include all embodiments falling within the scope of the appended claims. Also, in the drawings and the description, there have been disclosed exemplary embodiments of the invention and, although specific terms may have been employed, they are unless otherwise stated used in a generic and descriptive sense only and not for purposes of limitation, the scope of the invention therefore not being so limited. Moreover, the use of the terms first, second, etc. do not denote any order or importance, but rather the terms first, second, etc. are used to distinguish one element from another. Furthermore, the use of the terms a, an, etc. do not denote a limitation of quantity, but rather denote the presence of at least one of the referenced item.

What is claimed is:

1. An optical reading system comprising
a base having an opening therethough, said base being an optical filter that absorbs a range of light wavelengths;
a light emitting diode (“LED”) coupled to said base and arranged to emit light through said opening, said LED emitting light in said range of light wavelengths;
a first lens arranged adjacent said LED, said first lens arranged to emit light received from said LED;
a second lens arranged adjacent said first lens; and,
a complementary metal-oxide-semiconductor (“CMOS”) sensor adjacent said second lens and arranged to receive light received through said second lens, wherein said CMOS sensor is sensitive to light in said range of light wavelengths.

2. The optical reading system of claim 1 further comprising a first processor electrically coupled to receive signals indicative of pixel values from said CMOS sensor, said processor further being responsive to executable computer instructions to receive said signals and store image data.

3. The optical reading system of claim 2 further comprising a second processor electrically coupled to said first processor, said second processor being responsive to executable computer instructions to periodically retrieve said stored pixel values from registers coupled to said first processor.

4. The optical reading system of claim 3 further comprising a normally open relay electrically coupled to said second processor, wherein said second processor closes said relay in response to said image data indicating movement.

5. The optical reading system of claim 4 wherein said CMOS sensor is comprised of an array of pixels, wherein said array of pixels comprises 210 elements arranged in a 14×15 array.

6. The optical reading system of claim 1 wherein said range of wavelengths is centered about a wavelength of 630 nanometers.

7. An optical reading system for detecting movement of an object comprising:
an LED;
a lens member having a first lens portion adjacent said LED and arranged to focus light received from said LED on an area of interest and a second lens portion adjacent said first lens portion and arranged to received light reflected from said area of interest, wherein said second lens portion is shaped to provide a field of view corresponding to said area of interest; and,
a CMOS sensor adjacent said second lens and arranged to receive said reflected light and detect movement of said object within said area of interest.

8. The optical reading system of claim 7 wherein said first lens portion provides a depth field for said area of interest of at least 0.25 inches.

9. The optical reading system of claim 8 wherein said area of interest has a diameter of 0.06 inches to 0.08 inches.

10. The optical reading system of claim 9 further comprising a first processor electrically coupled to said CMOS sensor, said first processor being responsive to executable instructions to store image data received from said CMOS sensor regarding detected movement.

11. The optical reading system of claim 10 further comprising a second processor electrically coupled to transmit and receive signals from said first processor, wherein said second processor is responsive to executable computer instructions to periodically transmit an instruction to said first processor to transmit said stored image data.

12. The optical reading system of claim 11 further comprising a power source electrically coupled to said first processor, said second processor, said CMOS sensor and said LED.

13. The optical reading system of claim 12 wherein said first processor, said second processor, said CMOS sensor and said LED consume less than 100 micro-amps of electrical current from said power source during operation.

14. The optical reading system of claim 13 wherein said CMOS sensor and said LED consumes less than 50 micro-amps of electrical current from said power source during operation.

15. The optical reading system of claim 14 wherein said power source is a lithium thionyl chloride battery.

16. An optical reading system for detecting motion of an object within an area of interest, said optical reading system comprising:
a power source;
a base having an enclosed wall area with an opening therethrough, said base having a first portion outside of said enclosed wall area made from a translucent material having optical filtering properties for absorbing light in a wavelength range;
a processor within said enclosed wall area and electrically coupled to said power source;
a CMOS sensor electrically coupled to said processor and said power source, said CMOS sensor arranged within said enclosed wall area to receive light from said area of interest, said CMOS sensor being sensitive to said wavelength range; and,
an LED (54) electrically coupled to said processor and said power source, said LED being arranged within said enclosed wall area to emit light towards said area of interest.

17. The optical reading system of claim 16 further comprising:
a first lens adjacent said LED, said first lens being shaped to focus light from said LED on said area of interest with a depth of field of 0.25 inches; and,
a second lens adjacent said CMOS sensor, said second lens being shaped to focus light received from said area of interest.

18. The optical reading system of claim 17 wherein said LED emits light in said wavelength range.

19. The optical reading system of claim 18 wherein said wavelength range is centered about 630 nanometers.

20. The optical reading system of claim 19 wherein said first lens and said second lens are formed from a single molded piece.
